(19) United States
(12) Patent Application Publication
(10) Pub. No.: US 2025/0151528 A1
(43) Pub. Date: May 8, 2025

(54) DISPLAY APPARATUS

(71) Applicant: Samsung Display Co., Ltd., Yongin-si (KR)

(72) Inventors: Taehyun Kim, Yongin-si (KR); Byeonggeon Ko, Yongin-si (KR); Sunkwun Son, Yongin-si (KR); Donghee Shin, Yongin-si (KR)

(21) Appl. No.: 18/932,433

(22) Filed: Oct. 30, 2024

(30) Foreign Application Priority Data
Nov. 3, 2023 (KR) 10-2023-0151037

(51) Int. Cl. H10K 59/122; H10K 59/38; H10K 59/80

(52) U.S. Cl. CPC H10K 59/122; H10K 59/38; H10K 59/873

(57) ABSTRACT

A display apparatus includes: a substrate including first and second pixel areas, wherein a first subpixel, a second subpixel, and a third subpixel are arranged in the first pixel area and are configured to emit light of different colors; a plurality of light-emitting elements on the substrate to respectively correspond to the first subpixel, the second subpixel, and the third subpixel; and a bank layer on the plurality of light-emitting elements and including a first opening, a second opening, and a third opening, the first opening corresponding to the first subpixel, the second opening corresponding to the second subpixel, and the third opening corresponding to the third subpixel, wherein the first opening, the second opening, and the third opening are arranged in a first direction, and a first portion of the third opening extends in the first direction and overlaps the second pixel area.

### CROSS-REFERENCE TO RELATED APPLICATION

The present application claims priority to and the benefit of Korean Patent Application No. 10-2023-0151037, filed on Nov. 3, 2023, in the Korean Intellectual Property Office, the entire disclosure of which is incorporated herein by reference.

### BACKGROUND

### 1. Field

Aspects of one or more embodiments relate to a structure of a display apparatus.

### 2. Description of the Related Art

Display apparatuses visually display data. A display apparatus may include a substrate divided into a display area and a peripheral area. The display area may be formed with scan lines and data lines, which are insulated from each other, and may include a plurality of pixels. Also, a thin-film transistor corresponding to each of the pixels and a pixel electrode electrically connected to the thin-film transistor may be provided in the display area. In addition, an opposite electrode common to the pixels may be provided in the display area. Various wires that transfer electrical signals to the display area, a scan driver, a data driver, a controller, a pad portion, etc. may be located in the peripheral area.

Display apparatuses may be used for various purposes. Accordingly, various designs and techniques may be utilized to relatively improve the quality of display apparatuses.

The above information disclosed in this Background section is only for enhancement of understanding of the background and therefore the information discussed in this Background section does not necessarily constitute prior art.

### SUMMARY

Aspects of one or more embodiments include a display apparatus having relatively improved resolution to display images with excellent quality. However, the disclosed embodiments are examples and do not limit the scope of embodiments according to the present disclosure.

Additional aspects will be set forth in part in the description which follows and, in part, will be apparent from the description, or may be learned by practice of the presented embodiments of the disclosure.

According to some embodiments, a display apparatus includes a substrate including a first pixel area and a second pixel area adjacent to the first pixel area, wherein a first subpixel, a second subpixel, and a third subpixel are arranged in the first pixel area and emit light of different colors, a plurality of light-emitting elements on the substrate to respectively correspond to the first subpixel, the second subpixel, and the third subpixel, and a bank layer on the plurality of light-emitting elements and including a first opening, a second opening, and a third opening, the first opening corresponding to the first subpixel, the second opening corresponding to the second subpixel, and the third opening corresponding to the third subpixel, wherein the first opening, the second opening, and the third opening are arranged in a first direction, and a first portion of the third opening extends in the first direction and overlaps the second pixel area.

According to some embodiments, a fourth subpixel, a fifth subpixel, and a sixth subpixel may be arranged in the second pixel area, the fourth subpixel, the fifth subpixel, and the sixth subpixel emitting light of different colors, the bank layer may further include a fourth opening corresponding to the fourth subpixel, a fifth opening corresponding to the fifth subpixel, and a sixth opening corresponding to the sixth subpixel, the fourth opening, the fifth opening, and the sixth opening may be arranged in the first direction, and a first portion of the fourth opening may extend in an opposite direction to the first direction and overlap the first pixel area.

According to some embodiments, the first pixel area and the second pixel area may be repeatedly arranged.

According to some embodiments, the first subpixel and the fourth subpixel may emit light of a same color, the second subpixel and the fifth subpixel may emit light of a same color, and the third subpixel and the sixth subpixel may emit light of a same color.

According to some embodiments, the first opening and the fourth opening may have a same area but different shapes, and the third opening and the sixth opening may have a same area but different shapes.

According to some embodiments, each of the first to the sixth openings may include a first portion and a second portion that extends from one side of the first portion in a second direction crossing the first direction, and a width of the first portion in the first direction may be greater than a width of the second portion in the first direction.

According to some embodiments, an area of the first portion of the third opening may be greater than an area of the first portion of the sixth opening, and an area of the second portion of the third opening may be less than an area of the second portion of the sixth opening.

According to some embodiments, an area of the first portion of the fourth opening may be greater than an area of the first portion of the first opening, and an area of the second portion of the fourth opening may be less than an area of the second portion of the first opening.

According to some embodiments, with respect to the second direction, each of the first opening, the third opening, and the fifth opening, the first portion may have the first portion in an upper portion thereof and the second portion in a lower portion thereof, and each of the second opening, the fourth opening, and the sixth opening may have the second portion in an upper portion thereof and the first portion in a lower portion thereof.

According to some embodiments, with respect to the second direction, the first portion of the third opening may face the first portion of the fourth opening.

According to some embodiments, at least a portion of the first portion may have a circular, quadrangular, or polygonal planar shape.

According to some embodiments, at least one of the first to the sixth openings may further include a third portion, and the third portion may be a portion that extends from at least one of the first portion or the second portion.

According to some embodiments, at least one of the first to third openings may have an L-shape or a T-shape.

According to some embodiments, the display apparatus may further include a quantum dot layer or a light-transmissive layer located in the first to third openings.

According to one or more embodiments, a display apparatus including a first pixel unit and a second pixel unit, the first pixel unit including a first subpixel, a second subpixel, and a third subpixel that emit light of different colors, and the second pixel unit including a fourth subpixel, a fifth subpixel, and a sixth subpixel that emit light of different colors includes a plurality of light-emitting elements arranged to respectively correspond to the first to sixth subpixels, and a bank layer on the plurality of light-emitting elements and including a first opening, a second opening, a third opening, a fourth opening, a fifth opening, and a sixth opening, the first opening corresponding to the first subpixel, the second opening corresponding to the second subpixel, the third opening corresponding to the third subpixel, the fourth opening corresponding to the fourth subpixel, the fifth opening corresponding to the fifth subpixel, and the sixth opening corresponding to the sixth subpixel, wherein the first to the sixth openings are arranged in a first direction, a first portion of the third opening extends in the first direction, a first portion of the fourth opening extends in an opposite direction to the first direction, and with respect to a second direction crossing the first direction, the first portion of the third opening faces the first portion of the fourth opening.

According to some embodiments, the first pixel unit and the second pixel unit may be repeatedly arranged.

According to some embodiments, the first subpixel and the fourth subpixel may emit light of a same color, the second subpixel and the fifth subpixel may emit light of a same color, and the third subpixel and the sixth subpixel may emit light of a same color.

According to some embodiments, the first opening and the fourth opening may have a same area but different shapes, and the third opening and the sixth opening may have a same area but different shapes.

According to some embodiments, at least one of the first to the sixth openings may have an L-shape or a T-shape.

According to some embodiments, the first opening and the second opening may alternate with each other, the third opening and the fourth opening may alternate with each other, and the fifth opening and the sixth opening may alternate with each other.

According to some embodiments, each of the first to the sixth openings may include a first portion and a second portion that extends from one side of the first portion in the second direction, and a width of the first portion in the first direction may be greater than a width of the second portion in the first direction.

According to some embodiments, an area of the first portion of the third opening may be greater than an area of the first portion of the sixth opening, and an area of the first portion of the fourth opening may be greater than an area of the first portion of the first opening.

### BRIEF DESCRIPTION OF THE DRAWINGS

The above and other aspects, features, and characteristics of some embodiments of the present disclosure will be more apparent from the following description taken in conjunction with the accompanying drawings, in which:

FIG. 1 is a schematic plan view of a display apparatus according to some embodiments;

FIG. 2 is an equivalent circuit diagram of a light-emitting diode included in a display apparatus and a subpixel circuit electrically connected to the light-emitting diode, according to some embodiments;

FIG. 3 is a schematic cross-sectional view of each subpixel of a display apparatus, according to some embodiments;

FIG. 4 is a schematic diagram of each optical portion of a functional layer of FIG. 2 according to some embodiments;

FIG. 5 is a schematic plan view of a display apparatus according to some embodiments;

FIG. 6 is a schematic cross-sectional view of a display apparatus according to some embodiments;

FIG. 7 is a schematic plan view of a display apparatus according to some embodiments;

FIG. 8 is a schematic plan view of a display apparatus according to some embodiments; and

FIG. 9 is a schematic plan view of a display apparatus according to some embodiments.

### DETAILED DESCRIPTION

Reference will now be made in more detail to aspects of some embodiments, which are illustrated in the accompanying drawings, wherein like reference numerals refer to like elements throughout. In this regard, embodiments according to the present disclosure may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any combination of a, b, and/or c.

Because various modifications may be applied and one or more embodiments may be implemented, specific embodiments will be shown in the drawings and described in more detail in the detailed description. Effects and features, and methods for achieving them will be clarified with reference to embodiments described below in more detail with reference to the drawings. However, the embodiments may have different forms and should not be construed as being limited to the descriptions set forth herein.

Hereinafter, the embodiments will now be described in more detail with reference to the accompanying drawings. When described with reference to the drawings, identical or corresponding elements will be given the same reference numerals, and redundant description of these elements will be omitted.

It will be understood that although terms “first” and “second” may be used herein to describe various elements, these elements should not be limited by these terms and these terms are only used to distinguish one element from another.

In the following embodiments, the singular forms include the plural forms unless the context clearly indicates otherwise.

It will be understood that terms “comprise,” “include,” and “have” used herein specify the presence of stated features or elements, but do not preclude the presence or addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated for convenience of description. For example, because sizes and thicknesses of elements in the drawings are arbitrarily illustrated for convenience of explanation, the following embodiments are not limited thereto.

When a certain embodiment may be implemented differently, a specific process order may be performed differently from the described order. As an example, two processes that are successively described may be performed substantially simultaneously or performed in an order opposite to the order described.

It will be understood that when a layer, region, or element is referred to as being “connected to” another layer, region, or element, it may not only be “directly connected to” the other layer, region, or element, but also be “indirectly connected to” the other layer, region, or element with one or more intervening layers, regions, or elements therebetween. For example, as used herein, when a layer, region, or element is referred to as being electrically connected to another element, it may be directly electrically connected to the other layer, region, or element or indirectly electrically connected to the other layer, region, or element via intervening layers, regions, or elements.

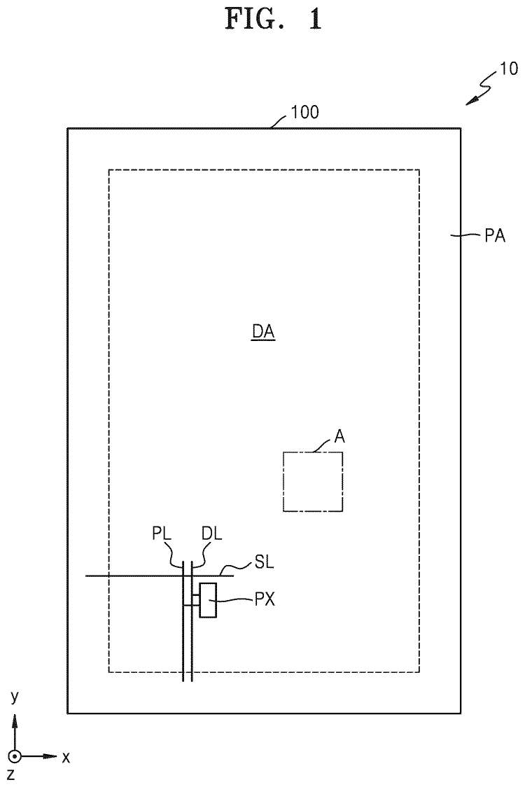

FIG. 1 is a schematic plan view of a display apparatus according to some embodiments.

Referring to FIG. 1, the display apparatus according to some embodiments includes a display panel 10. The display apparatus may be any apparatus that includes the display panel 10. For example, the display apparatus may be one of various apparatuses or electronic devices such as a smartphone, a tablet, a laptop computer, a television, or a billboard.

The display panel 10 includes a display area DA and a peripheral area PA located outside (e.g., in a periphery or outside a footprint of) the display area DA. FIG. 1 shows that the display area DA has a rectangular shape. However, embodiments according to the present disclosure are not limited thereto. The display area DA may have other shapes such as a circular shape, an elliptical shape, a polygonal shape, or a specific figure shape.

The display area DA is an area where images are displayed, and a plurality of subpixels PX may be arranged in the display area DA. Each subpixel PX may include a light-emitting element such as an organic light-emitting diode. Each subpixel PX may emit, for example, red, green, or blue light. The subpixel PX may be connected to a sub-pixel circuit including a thin-film transistor (TFT), a storage capacitor, or the like. The subpixel circuit may include a scan line SL configured to transfer a scan signal, a data line DL that crosses the scan line SL and configured to transfer a data signal, and a driving voltage line PL configured to supply a driving voltage. The scan line SL may extend in an x-direction, and the data line DL and the driving voltage line PL may extend in a y-direction.

The subpixel PX may emit light having a luminance corresponding to an electrical signal from the subpixel circuit electrically connected to the subpixel PX. The display area DA may display a certain image through light emitted from the subpixel PX. For reference, the subpixel PX may be defined as an area that emits light of any one color among red, green, and blue, as described above.

The peripheral area PA may be an area in which the subpixel PX is not arranged and may be an area where images are not displayed. A power supply line for driving the subpixel PX may be located in the peripheral area PA. Also, a printed circuit board including a driving circuit portion or a terminal portion to which a driver integrated circuit (IC) is connected may be arranged in the peripheral area PA.

For reference, because the display panel 10 includes a first substrate 100, the first substrate 100 may also include the display area DA and the peripheral area PA.

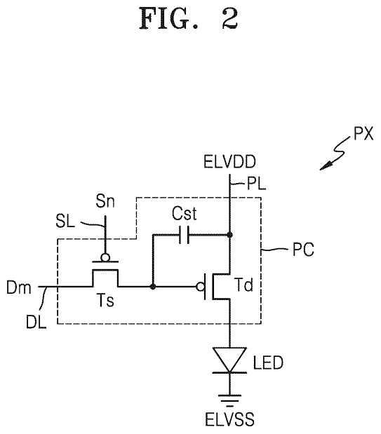

FIG. 2 is an equivalent circuit diagram of a light-emitting diode LED included in the display apparatus and a subpixel circuit PC electrically connected to the light-emitting diode LED, according to some embodiments.

Referring to FIG. 2, the subpixel circuit PC may be electrically connected to the light-emitting diode LED, and one light-emitting diode LED may correspond to one subpixel PX.

The subpixel circuit PC may include a first transistor Td, a second transistor Ts, and a storage capacitor Cst.

The second transistor Ts, which is a switching transistor, may be connected to the scan line SL and the data line DL, turned on in response to a switching signal input from the scan line SL, and configured to transfer, to the first transistor Td, a data signal input from the data line DL. One end of the storage capacitor Cst may be electrically connected to the second transistor Ts, and the other end of the storage capacitor Cst may be electrically connected to a driving voltage line PL, and the storage capacitor Cst may store a voltage corresponding to a difference between a voltage received from the second transistor Ts and a driving power voltage ELVDD supplied through the driving voltage line PL.

The first transistor Td, which is a driving transistor, may be connected to the driving voltage line PL and the storage capacitor Cst and configured to control the magnitude of a driving current flowing through the light-emitting diode LED from the driving voltage line PL in response to a value of the voltage stored in the storage capacitor Cst. The light-emitting diode LED may emit light having a certain luminance according to the driving current. An opposite electrode of the light-emitting diode LED may receive an electrode power voltage ELVSS.

Although FIG. 2 shows that the subpixel circuit PC includes two TFTs and one storage capacitor, one or more embodiments are not limited thereto. According to some embodiments, the subpixel circuit PC may include seven TFTs and one storage capacitor. According to some embodiments, the subpixel circuit PC may include two or more storage capacitors. In various embodiments, the subpixel circuit PC may include additional components or fewer components without departing from the spirit and scope of embodiments according to the present disclosure

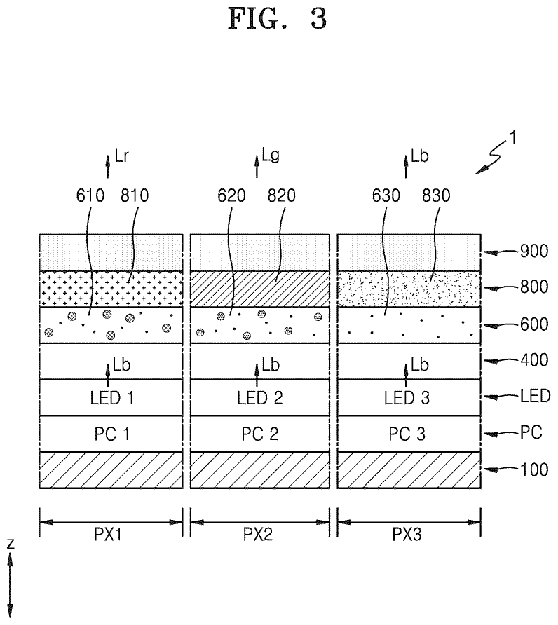

FIG. 3 is a schematic cross-sectional view of each subpixel of a display apparatus 1, according to some embodiments.

Referring to FIG. 3, the plurality of subpixels PX (see FIG. 1) may include a first subpixel PX1, a second subpixel PX2, and a third subpixel PX3. The first subpixel PX1 may be a red pixel, the second subpixel PX2 may be a green pixel, and the third subpixel PX3 may be a blue pixel. The first subpixel PX1, the second subpixel PX2, and the third subpixel PX3 are areas that may emit red, green, and blue light, respectively. The display apparatus 1 may display images by using light emitted from the plurality of subpixels PX.

The display apparatus 1 may include the subpixel circuit PC on the first substrate 100. The subpixel circuit PC may include first to third subpixel circuits PC1, PC2, and PC3, and the first to third subpixel circuits PC1, PC2, and PC3 may be electrically connected to first to third light-emitting diodes LED1, LED2, and LED3 of the light-emitting diode LED, respectively.

The first to third light-emitting diodes LED1, LED2, and LED3 may each include an organic light-emitting diode including an organic material. Alternatively, the first to third light-emitting diodes LED1, LED2, and LED3 may each include an inorganic light-emitting diode including an inorganic material. The inorganic light-emitting diode may include a PN junction diode including inorganic semiconductor-based materials. When a forward voltage is applied to a PN-junction diode, holes and electrons are injected and energy created by recombination of the holes and the electrons is converted into light energy, and thus, light of a preset color may be emitted. The above inorganic light-emitting diode may have a width of several to hundreds of micrometers or several to several hundreds of nanometers. Alternatively, the light-emitting diode LED may be a light-emitting diode including quantum dots. As described above, an emission layer of the light-emitting diode LED may include an organic material, an inorganic material, or quantum dots, both an organic material and quantum dots, or both an inorganic material and quantum dots.

The first to third light-emitting diodes LED1, LED2, and LED3 may emit light of the same color. For example, light (e.g., blue light Lb) emitted from the first to third light-emitting diodes LED1, LED2, and LED3 may pass through a functional layer 600 after passing through an encapsulation layer 400 on the light-emitting diode LED.

The functional layer 600 may include optical portions that convert the color of the light (e.g., the blue light Lb) emitted from the light-emitting diode LED or transmit the light without converting the color of the light. For example, the functional layer 600 may include first and second quantum dot layers 610 and 620 that convert the light (e.g., the blue light Lb) emitted from the light-emitting diode LED into light of another color, and a light-transmissive layer 630 that transmits the light (e.g., the blue light Lb) emitted from the light-emitting diode LED without converting the color of the light. The functional layer 600 may include the first quantum dot layer 610 corresponding to the first subpixel PX1 that emits red light, the second quantum dot layer 620 corresponding to the second subpixel PX2, and the light-transmissive layer 630 corresponding to the third subpixel PX3 that emits blue light. The first quantum dot layer 610 may convert the blue light Lb into red light Lr, and the second quantum dot layer 620 may convert the blue light Lb into green light Lg. The light-transmissive layer 630 may pass the blue light Lb without converting the blue light Lb.

A color filter layer 800 may be located on the functional layer 600. The color filter layer 800 may include first to third color filters 810, 820, and 830 of different colors. For example, the first color filter 810 may be a red color filter, the second color filter 820 may be a green color filter, and the third color filter 830 may be a blue color filter.

Light color-converted by and light transmitted by the functional layer 600 pass through the first to third color filters 810, 820, and 830 such that color purity may be relatively improved. Also, the color filter layer 800 may prevent or significantly reduce external light (e.g., light incident from the outside of the display apparatus 1 toward the display apparatus 1) from being reflected and seen by a user.

A second substrate 900 may be located on the color filter layer 800. The second substrate 900 may include glass or a light-transmissive organic material. For example, the second substrate 900 may include a light-transmissive organic material such as acrylic resin.

According to some embodiments, the second substrate 900 is a type of substrate, and after the color filter layer 800 and the functional layer 600 are formed on the second substrate 900, the functional layer 600 may be integrated to face the encapsulation layer 400.

Alternatively, after the functional layer 600 and the color filter layer 800 are sequentially formed on the encapsulation layer 400, the second substrate 900 may be formed by being directly applied and cured on the color filter layer 800. According to some embodiments, another optical film, for example, an anti-reflection (AR) film, may be located on the second substrate 900.

The display apparatus 1 having the above structure may include a television, a billboard, a movie theater screen, a monitor, a tablet personal computer (PC), a laptop computer, or the like.

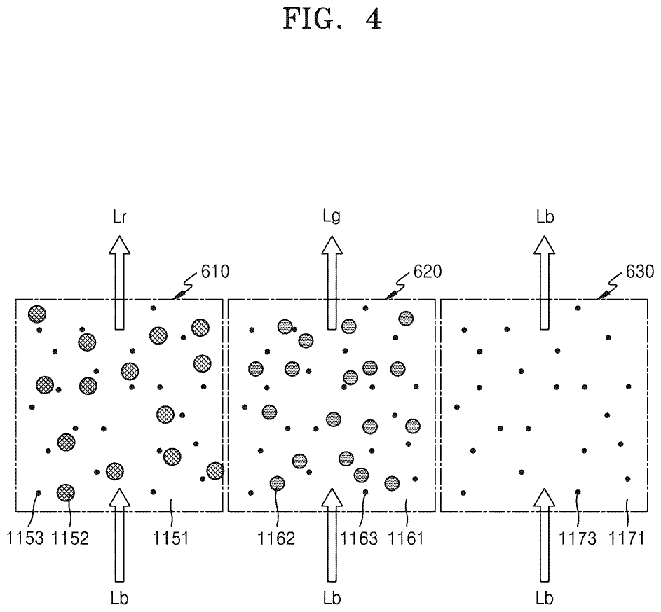

FIG. 4 is a schematic diagram of each optical portion of a functional layer of FIG. 2.

Referring to FIG. 4, the first quantum dot layer 610 may convert incident blue light Lb into red light Lr. As shown in FIG. 4, the first quantum dot layer 610 may include a first photosensitive polymer 1151, and first quantum dots 1152 and first scattering particles 1153 dispersed in the first photosensitive polymer 1151.

The first quantum dots 1152 may be excited by the blue light Lb to isotopically emit red light Lr having a wavelength lower than the wavelength of the blue light Lb. The first photosensitive polymer 1151 may include an organic material having light transmission properties. The first scattering particles 1153 scatter the blue light Lb that is not absorbed by the first quantum dots 1152 to cause more first quantum dots 1152 to be excited such that the color conversion efficiency may be increased. The first scattering particles 1153 may include, for example, titanium oxide (TiO₂) or metal particles. The first quantum dots 1152 may be selected from among a group II-VI compound, a group III-V compound, a group IV-VI compound, a group IV element, a group IV compound, and any combinations thereof.

The second quantum dot layer 620 may convert the incident blue light Lb into green light Lg. As shown in FIG. 4, the second quantum dot layer 620 may include a second photosensitive polymer 1161, and second quantum dots 1162 and second scattering particles 1163 dispersed in the second photosensitive polymer 1161.

The second quantum dots 1162 may be excited by the blue light Lb to isotopically emit green light Lg having a wavelength lower than the wavelength of the blue light Lb. The second photosensitive polymer 1161 may include an organic material having light transmission properties.

The second scattering particles 1163 scatter the blue light Lb that is not absorbed by the second quantum dots 1162 to cause more second quantum dots 1162 to be excited such that the color conversion efficiency may be increased. The second scattering particles 1163 may include, for example, TiO₂ or metal particles. The second quantum dots 1162 may be selected from among a group II-VI compound, a group III-V compound, a group IV-VI compound, a group IV element, a group IV compound, and any combinations thereof.

According to some embodiments, the first quantum dots 1152 and the second quantum dots 1162 may be the same material. In this case, sizes of the first quantum dots 1152 may be greater than sizes of the second quantum dots 1162.

The light-transmissive layer 630 may transmit the blue light Lb incident on the light-transmissive layer 630 without converting the blue light Lb. As shown in FIG. 4, the light-transmissive layer 630 may include a third photosensitive polymer 1171 in which third scattering particles 1173 are dispersed. For example, the third photosensitive polymer 1171 may include, for example, an organic material having light transmission properties, such as silicon resin or epoxy resin, and the third photosensitive polymer 1171 and the first and second photosensitive polymers 1151 and 1161 may include the same material. The third scattering particles 1173 may scatter and emit blue light Lb, and the third scattering particles 1173 and the first and second scattering particles 1153 and 1163 may include the same material.

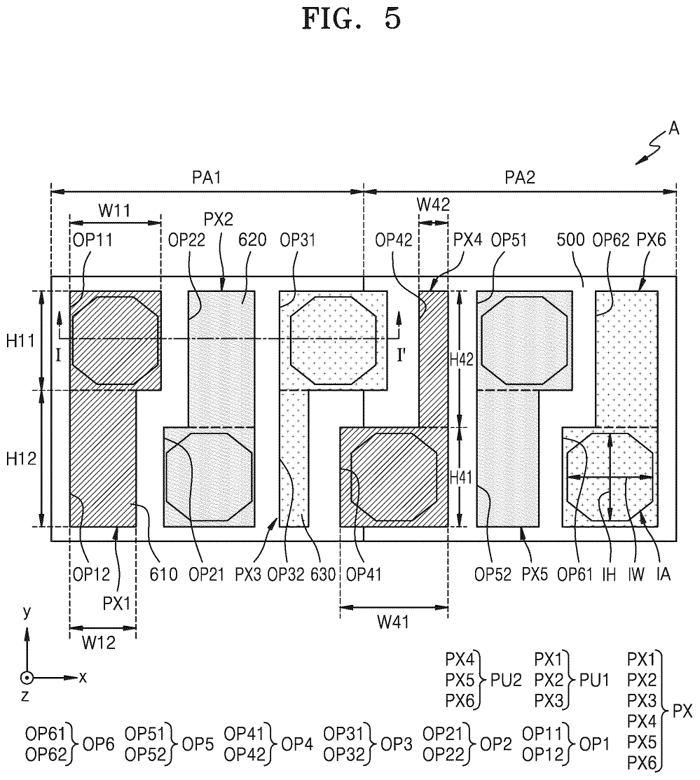

FIG. 5 is a schematic plan view of the display apparatus according to some embodiments. FIG. 5 may be a schematic enlarged plan view of a region A of FIG. 1.

Referring to FIG. 5, the display area DA (see FIG. 1) of the display apparatus may include a first pixel area PA1 and a second pixel area PA2. Each of the first pixel area PA1 and the second pixel area PA2 is an area in which a plurality of subpixels may be arranged, and in the display area DA (see FIG. 1), the first pixel area PA1 and the second pixel area PA2 may be repeatedly arranged.

A first pixel unit PU1 may be arranged in the first pixel area PA1, and a second pixel unit PU2 may be arranged in the second pixel area PA2. The first pixel unit PU1 and the second pixel unit PU2 may be defined as a subpixel assembly in which a plurality of subpixels PX arranged according to a pixel array structure are grouped into preset units. According to some embodiments, each of the first pixel unit PU1 and the second pixel unit PU2 may be a subpixel assembly of a minimum unit that repeats in a certain pixel array structure.

In the display area DA (see FIG. 1), the plurality of subpixels PX may form the first pixel unit PU1 and the second pixel unit PU2. For example, the first pixel unit PU1 may be a subpixel assembly including the first subpixel PX1 that emits red light, the second subpixel PX2 that emits green light, and the third subpixel PX3 that emits blue light. Similarly, the second pixel unit PU2 may be a subpixel assembly including a fourth subpixel PX4 that emits red light, a fifth subpixel PX5 that emits green light, and a sixth subpixel PX6 that emits blue light. The first pixel unit PU1 is arranged in the first pixel area PA1, the second pixel unit PU2 is arranged in the second pixel area PA2, and the first pixel unit PU1 and the second pixel unit PU2 may be adjacent to each other. In the display area DA (see FIG. 1), the first pixel unit PU1 and the second pixel unit PU2 may be repeatedly arranged in a first direction (e.g., an x-direction) and a second direction (e.g., a y-direction).

According to some embodiments, as shown in FIG. 5, each of the first pixel unit PU1 and the second pixel unit PU2 may have a structure in which the plurality of subpixels PX are arranged in the first direction (e.g., the x-direction). For example, in the first pixel area PA1, the first subpixel PX1, the second subpixel PX2, and the third subpixel PX3 may be arranged in the first direction (e.g., the x-direction), and in the second pixel area PA2, the fourth subpixel PX4, the fifth subpixel PX5, and the sixth subpixel PX6 may be arranged in the first direction (e.g., the x-direction).

Sizes, that is, areas, of the first to sixth subpixels PX1, PX2, PX3, PX4, PX5, and PX6 may be different. For example, the area of the third subpixel PX3 may be smaller than the area of the first subpixel PX1 and the area of the second subpixel PX2. However, areas of subpixels PX that emit light of the same color may be identical to each other. For example, the areas of the first subpixel PX1 and the fourth subpixel PX4 that emit red light may be identical to each other, the areas of the second subpixel PX2 and the fifth subpixel PX5 that emit green light may be identical to each other, and the areas of the third subpixel PX3 and the sixth subpixel PX6 that emit blue light may be identical to each other. An area of each of the plurality of subpixels PX may be defined by an opening of a bank layer 500 to be described in more detail below. This will be described in more detail below.

As described above, the first subpixel PX1 includes the first light-emitting diode LED1, the first quantum dot layer 610, and the first color filter 810 and may thus emit red light, the second subpixel PX2 includes the second light-emitting diode LED2, the second quantum dot layer 620, and the second color filter 820 and may thus emit green light, and the third subpixel PX3 includes the third light-emitting diode LED3, the light-transmissive layer 630, and the third color filter 830 and may thus emit blue light. That is, the first subpixel PX1 may include the first quantum dot layer 610, the second subpixel PX2 may include the second quantum dot layer 620, and the third subpixel PX3 may include the light-transmissive layer 630.

The bank layer 500 may include a plurality of openings respectively corresponding to the plurality of subpixels PX. In this case, the first quantum dot layer 610, the second quantum dot layer 620, and the light-transmissive layer 630 may be arranged in the plurality of openings of the bank layer 500. According to some embodiments, the bank layer 500 may include a first opening OP1 corresponding to the first subpixel PX1, a second opening OP2 corresponding to the second subpixel PX2, a third opening OP3 corresponding to the third subpixel PX3, a fourth opening OP4 corresponding to the fourth subpixel PX4, a fifth opening OP5 corresponding to the fifth subpixel PX5, and a sixth opening OP6 corresponding to the sixth subpixel PX6.

The first subpixel PX1 and the fourth subpixel PX4 emit red light, and accordingly, the first quantum dot layer 610 may be arranged in the first opening OP1 and the fourth opening OP4. The second subpixel PX2 and the fifth subpixel PX5 emit green light, and accordingly, the second quantum dot layer 620 may be arranged in the second opening OP2 and the fifth opening OP5. The third subpixel PX3 and the sixth subpixel PX6 emit blue light, and accordingly, the light-transmissive layer 630 may be arranged in the third opening OP3 and the sixth opening OP6.

In this case, the first quantum dot layer 610, the second quantum dot layer 620, and the light-transmissive layer 630 arranged in the plurality of openings of the bank layer 500 may be applied by an inkjet printing process. The inkjet printing process is a method of forming a thin film using an inkjet printing system including an inkjet printing main body and an inkjet head having a plurality of nozzles. Ink is dropped onto a substrate through the nozzles of the inkjet head, and the dropped ink may spread around a drop location to form a uniform film thickness. Accordingly, when each opening of the bank layer 500 has a size greater than the size of an inkjet area IA, which has a sufficient margin for ink to be ejected and spread, the display apparatus may have more uniform luminance.

To this end, according to some embodiments, each of the plurality of openings of the bank layer 500 arranged in the display apparatus may include a first portion including the inkjet area IA and a second portion extending in the second direction (e.g., the y-direction) from one side of the first portion.

For example, the first opening OP1 may include a first portion OP11 and a second portion OP12, the second opening OP2 may include a first portion OP21 and a second portion OP22, and the third opening OP3 may include a first portion OP31 and a second portion OP32. Similarly, the fourth opening OP4 may include a first portion OP41 and a second portion OP42, the fifth opening OP5 may include a first portion OP51 and a second portion OP52, and the sixth opening OP6 may include a first portion OP61 and a second portion OP62.

Each of the first portions OP11, OP21, OP31, OP41, OP51, and OP61 is an area where ink may be dropped, and the inkjet area IA described above may be arranged in each of the first portions OP11, OP21, OP31, OP41, OP51, and OP61. Accordingly, an area of each of the first portions OP11, OP21, OP31, OP41, OP51, and OP61 may be greater than an area of the inkjet area IA. For example, the inkjet area IA may require at least one of a horizontal width IW or a vertical width IH to be 35 μm or more. When both the horizontal width IW and the vertical width IH of 35 μm or more are secured, the process time (Takt time) of an inkjet process for forming the first quantum dot layer 610, the second quantum dot layer 620, and the light-transmissive layer 630 may be shortened, and excellent thickness uniformity of the dropped and spread ink may be obtained. Accordingly, when seen in a third direction (e.g., a z-direction), the inkjet area IA may have a regular octagonal shape with the horizontal width IW and the vertical width IH of 35 μm, and each of the first portions OP11, OP21, OP31, OP41, OP51, and OP61 may have a quadrangular shape greater than the inkjet area IA.

However, when a high-resolution image is to be implemented, sizes of the first pixel area PA1 and the second pixel area PA2 arranged in the display area DA (see FIG. 1) need to be reduced, and sizes of the first to sixth openings OP1, OP2, OP3, OP4, OP5, and OP6 may be limited to fit the first pixel area PA1 and the second pixel area PA2. Accordingly, each of the first portions OP11, OP21, OP31, OP41, OP51, and OP61 has a quadrangular shape greater than the inkjet area IA, and widths of the second portions OP12, OP22, OP32, OP42, OP52, and OP62 in the first direction (e.g., the x-direction) may be less than widths of the first portions OP11, OP21, OP31, OP41, OP51, and OP61 in the first direction (e.g., the x-direction). For example, the second portions OP12, OP22, OP32, OP42, OP52, and OP62 may extend in the second direction (e.g., the y-direction) from one sides of the first portions OP11, OP21, OP31, OP41, OP51, and OP61, respectively, and may each have a rectangular shape having a horizontal width less than horizontal widths of the first portions OP11, OP21, OP31, OP41, OP51, and OP61.

Due to the above structure, at least one of the first to sixth openings OP1, OP2, OP3, OP4, OP5, or OP6 may have an L-shape. For example, with respect to the first direction (e.g., the x-direction), a left end of the first portion OP11 of the first opening OP1 may be arranged on the same line as a left end of the second opening OP12 of the first opening OP1, and a right end of the first portion OP11 of the first opening OP1 may be arranged to protrude further than a right end of the second opening OP12 of the first opening OP1. Similarly, with respect to the first direction (e.g., the x-direction), a right end of the first portion OP21 of the second opening OP2 may be arranged on the same line as a right end of the second portion OP22 of the second opening OP2, and a left end of the first portion OP21 of the second opening OP2 may be arranged to protrude further than a left end of the second portion OP22 of the second opening OP2.

Moreover, as described above, areas of openings that emit light of the same color may be substantially identical to each other. For example, an area of the first opening OP1 and an area of the fourth opening OP4 may be identical to each other, an area of the second opening OP2 and an area of the fifth opening OP5 may be identical to each other, and an area of the third opening OP3 and an area of the sixth opening OP6 may be identical to each other.

However, even though the openings emit light of the same color, their shapes may be different. That is, planar areas of the first opening OP1 and the fourth opening OP4 may be identical to each other, but a shape of the first opening OP1 may be different from a shape of the fourth opening OP4. Similarly, a shape of the second opening OP2 may be different from a shape of the fifth opening OP5, and a shape of the third opening OP3 may be different from a shape of the sixth opening OP6.

For example, even though each of the first opening OP1 and the fourth opening OP4 has an L-shape, an area of each of the first portions OP11 and OP41 may be different from an area of each of the second portions OP12 and OP42. As shown in FIG. 5, an area of the first portion OP41 of the fourth opening OP4 may be greater than an area of the first portion OP11 of the first opening OP1, and an area of the second portion OP42 of the fourth opening OP4 may be less than an area of the second opening OP12 of the first opening OP1. In this case, the area of the first portion OP11 of the first opening OP1 may be referred to as an area obtained by multiplying a first horizontal width W11 by a second vertical width H11, and the area of the second opening OP12 of the first opening OP1 may be referred to as an area obtained by multiplying a second horizontal width W12 by a second vertical width H12. The area of the first portion OP41 of the fourth opening OP4 may be referred to as an area obtained by multiplying a third horizontal width W41 by a third vertical width H41, and the area of the second portion OP42 of the fourth opening OP4 may be referred to as an area obtained by multiplying a fourth horizontal width W42 by a fourth vertical width H42. Similarly, each of the third opening OP3 and the sixth opening OP6 may have an L-shape, but an area of the first portion OP31 of the third opening OP3 may be greater than an area of the first portion OP61 of the sixth opening OP6, and an area of the second portion OP32 of the third opening OP3 may be less than an area of the second portion OP62 of the sixth opening OP6.

As described above, this is to form the first to sixth subpixels PX1, PX2, PX3, PX4, PX5, and PX6 in the first pixel area PA1 and the second pixel area PA2, which are reduced in size to achieve high resolution. For example, when the display apparatus is a high-resolution product of 220 ppi or higher, a length of a width of the first pixel area PA1 in the first direction (e.g., the x-direction) may be about 115 μm. Because each of the first subpixel PX1, the second subpixel PX2, and the third subpixel PX3 includes the inkjet area IA, an area having each horizontal width in the first direction (e.g., the x-direction) of at least 35 μm may be required. In addition, in order to stably drop ink required to form the first quantum dot layer 610, the second quantum dot layer 620, and the light-transmissive layer 630, an area of a certain length or more may also be required between the first opening OP1, the second opening OP2, and the third opening OP3. Ultimately, when the first to third openings OP1, OP2, and OP3 each including the inkjet area IA are arranged side by side, the first pixel area PA1 may be insufficient.

Accordingly, the display apparatus according to some embodiments may have a structure in which the subpixels PX are shared between the first pixel area PA1 and the second pixel area PA2, which are arranged adjacent to each other. That is, the third subpixel PX3, which is arranged closest to the second pixel area PA2 among the subpixels PX arranged in the first pixel area PA1, and the fourth subpixel PX4, which is arranged closest to the first pixel area PA1 among the subpixels PX arranged in the second pixel area PA2, may be arranged to overlap both the first pixel area PA1 and the second pixel area PA2. For example, the first portion OP31 of the third opening OP3 may extend from the first pixel area PA1 to the second pixel area PA2 in the first direction (e.g., the x-direction) and may also partially overlap the second pixel area PA2. Similarly, the first portion OP41 of the fourth opening OP4 may extend from the second pixel area PA2 to the first pixel area PA1 in an opposite direction (e.g., a −x direction) to the first direction and may also partially overlap the first pixel area PA1.

For the shared design as described above, the size of the first portion OP31 of the third opening OP3 may be greater than the size of the first portion OP61 of the sixth opening OP6, and the size of the first portion OP41 of the fourth opening OP4 may also be greater than the size of the first portion OP11 of the first opening OP1. However, because areas of areas that emit light of the same color need to be identical to each other, the second portion OP32 of the third opening OP3 may be less than the second portion OP62 of the sixth opening OP6, and the second portion OP42 of the fourth opening OP4 may also be less than the second opening OP12 of the first opening OP1.

Moreover, in order to more efficiently use a space of the first pixel area PA1 and the second pixel area PA2, which have limited sizes, the plurality of subpixels PX may be alternately arranged. That is, the first opening OP1 and the second opening OP2 may alternate with each other, the third opening OP3 and the fourth opening OP4 may alternate with each other, and the fifth opening OP5 and the sixth opening OP6 may alternate with each other. For example, with respect to the second direction (e.g., the y-direction), the first portions OP11, OP31, and OP51 may be arranged in upper portions of the first opening OP1, the third opening OP3, and the fifth opening OP5, and the second portions OP12, OP32, and OP52 may be arranged in lower portions of the first opening OP1, the third opening OP3, and the fifth opening OP5. Similarly, with respect to the second direction (e.g., the y-direction), the second portions OP22, OP42, and OP62 may be arranged in upper portions of the second opening OP2, the fourth opening OP4, and the sixth opening OP6, and the first portions OP21, OP41, and OP61 may be arranged in lower portions of the second opening OP2, the fourth opening OP4, and the sixth opening OP6.

For example, the first opening OP1, the third opening OP3, and the fifth opening OP5 may have a shape that is mirror-symmetrical to the L-shape with respect to an axis of the first direction (e.g., the x-direction), and the second opening OP2, the fourth opening OP4, and the sixth opening OP6 may have a shape that is mirror-symmetrical to the L-shape with respect to an axis of the second direction (e.g., the y-direction). Through the arrangement as described above, the first portion OP31 of the third opening OP3 and the first portion OP41 of the fourth opening OP4 may have structures facing each other with respect to the second direction (e.g., the y-direction). In other words, the first opening OP1 and the second opening OP2 are alternately arranged as a pair in a group, the third opening OP3 and the fourth opening OP4 are alternately arranged as a pair in a group, and the fifth opening OP5 and the sixth opening OP6 are alternately arranged as a pair in a group, and accordingly, waste of space in the first pixel area PA1 and the second pixel area PA2 may be significantly reduced, and high-resolution images may be implemented.

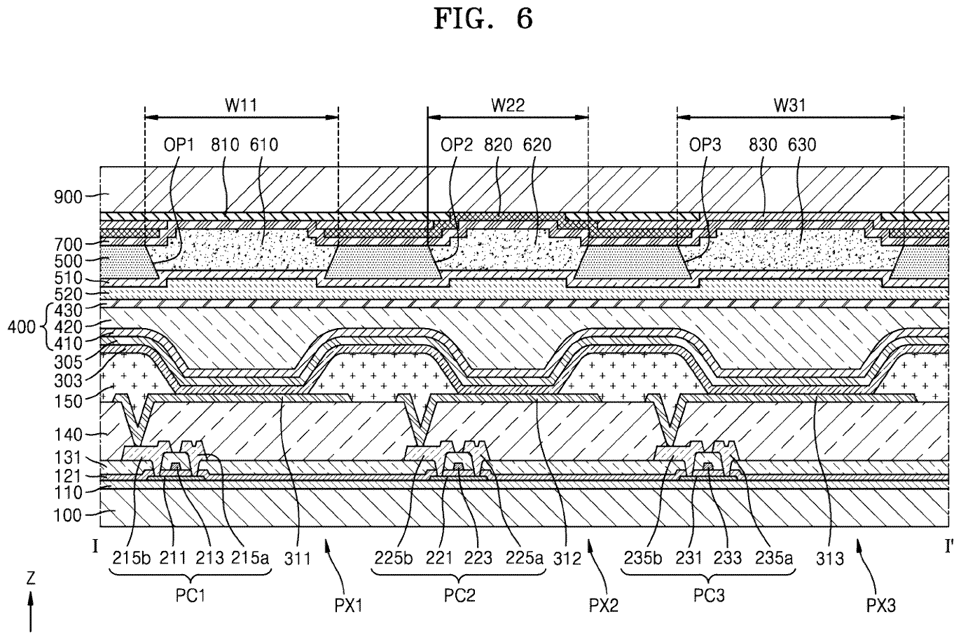

FIG. 6 is a schematic cross-sectional view of the display apparatus according to some embodiments. FIG. 6 is a schematic cross-sectional view illustrating a cross-section of the display apparatus taken along a line I-I′ of FIG. 5, according to some embodiments.

Referring to FIG. 6, the display apparatus may include the first substrate 100, a first pixel electrode 311, a second pixel electrode 312, a third pixel electrode 313, a pixel-defining layer 150, the encapsulation layer 400, the second substrate 900, the bank layer 500, the light-transmissive layer 630, the first quantum dot layer 610, and the second quantum dot layer 620.

The first substrate 100 may include glass, metal, or polymer resin. The first substrate 100 may include polyethersulfone, polyacrylate, polyetherimide, polyethylene naphthalate, polyethylene terephthalate, polyphenylene sulfide, polyarylate, polyimide, polycarbonate, or cellulose acetate propionate. Various modifications may be made to the first substrate 100. For example, the first substrate 100 may have a multilayer structure including two layers and a barrier layer, wherein the two layers include the above polymer resin and the barrier layer includes an inorganic material (e.g., silicon oxide, silicon nitride, silicon oxynitride, or the like).

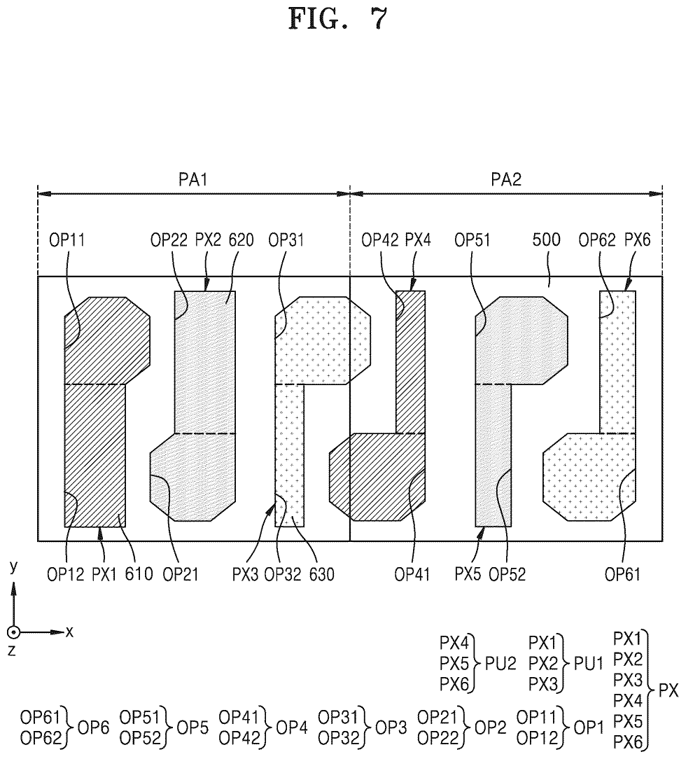

The first pixel electrode 311, the second pixel electrode 312, and the third pixel electrode 313 may be arranged above the first substrate 100. In addition to the first pixel electrode 311, the second pixel electrode 312, and the third pixel electrode 313, a first subpixel circuit PC1, a second subpixel circuit PC2, and a third subpixel circuit PC3, which are electrically connected to the first pixel electrode 311, the second pixel electrode 312, and the third pixel electrode 313, may also be arranged over the first substrate 100. That is, as shown in FIG. 7, the first pixel electrode 311 may be electrically connected to a first subpixel circuit PC1, the second pixel electrode 312 may be electrically connected to a second subpixel circuit PC2, and the third pixel electrode 313 may be electrically connected to a third subpixel circuit PC3. The first pixel electrode 311, the second pixel electrode 312, and the third pixel electrode 313 may be located on a planarization layer 140 to be described below, the planarization layer 140 being over the first substrate 100.

The first subpixel circuit PC1 may include a first semiconductor layer 211, a first gate electrode 213, a first source electrode 215a, and a first drain electrode 215b, the first semiconductor layer 211 including amorphous silicon, polycrystalline silicon, an organic semiconductor material, or an oxide semiconductor material. The first gate electrode 213 may include various conductive materials and may have various layered structures. For example, the first gate electrode 213 may include a molybdenum (Mo) layer and an aluminum (Al) layer. In this case, the first gate electrode 213 may have a layered structure of Mo/Al/Mo. Alternatively, the first gate electrode 213 may also include a titanium nitride (TiNₓ) layer, an Al layer, and/or a titanium (Ti) layer. The first source electrode 215a and the first drain electrode 215b may also include various conductive materials and may have various layered structures. For example, the first source electrode 215a and the first drain electrode 215b may include a Ti layer, an Al layer, and/or a copper (Cu) layer. In this case, the first source electrode 215a and the first drain electrode 215b may each have a layered structure of Ti/Al/Ti.

Although FIG. 6 shows that the first subpixel circuit PC1 includes both the first source electrode 215a and the first drain electrode 215b, one or more embodiments are not limited thereto. For example, a source region of the first semiconductor layer 211 of the first subpixel circuit PC1 may be integrally formed as a single body with a drain region of a semiconductor layer of another TFT, in which case the first subpixel circuit PC1 may not include the first source electrode 215a. In addition, the first source electrode 215a and/or the first drain electrode 215b may be a portion of a wire.

In order to secure insulation between the first semiconductor layer 211 and the first gate electrode 213, a gate insulating layer 121 may be between the first semiconductor layer 211 and the first gate electrode 213, the gate insulating layer 121 including an inorganic material such as silicon oxide, silicon nitride, and/or silicon oxynitride. Moreover, an interlayer insulating layer 131 may be located on the first gate electrode 213, the interlayer insulating layer 131 including an inorganic material such as silicon oxide, silicon nitride, and/or silicon oxynitride, and the first source electrode 215a and the first drain electrode 215b may be located on the interlayer insulating layer 131. As described above, an insulating layer including an inorganic material may be formed using chemical vapor deposition (CVD) or atomic layer deposition (ALD). This applies to the following embodiments and modifications thereof.

A buffer layer 110 may be between the first substrate 100 and the first subpixel circuit PC1 having the above structure, the buffer layer 110 including an inorganic material such as silicon oxide, silicon nitride, and/or silicon oxynitride. The buffer layer 110 may increase smoothness of an upper surface of the first substrate 100 or may prevent or significantly reduce penetration of impurities from the first substrate 100 or the like into the first semiconductor layer 211 of the first subpixel circuit PC1.

The second subpixel circuit PC2 located in the second subpixel PX2 may include a second semiconductor layer 221, a second gate electrode 223, a second source electrode 225a, and a second drain electrode 225b. The third subpixel circuit PC3 located in the third subpixel PX3 may include a third semiconductor layer 231, a third gate electrode 233, a third source electrode 235a, and a third drain electrode 235b. A structure of the second subpixel circuit PC2 and a structure of the third subpixel circuit PC3 are identical or similar to a structure of the first subpixel circuit PC1 located in the first subpixel PX1, and thus, descriptions thereof are not provided.

The planarization layer 140 may be located on the first subpixel circuit PC1. For example, as shown in FIG. 6, when a light-emitting element including the first pixel electrode 311 is arranged over the first subpixel circuit PC1, the planarization layer 140 covering the first subpixel circuit PC1 has a substantially flat upper surface such that the first pixel electrode 311 of the light-emitting element may be located on the flat surface. The planarization layer 140 may include an organic material such as acryl, benzocyclobutene (BCB), or hexamethyldisiloxane (HMDSO). Although FIG. 6 shows that the planarization layer 140 includes a single layer, various modifications may be made. For example, the planarization layer 140 may include a multilayer.

A light-emitting diode may be located in the first subpixel PX1, the light-emitting diode including the first pixel electrode 311, an opposite electrode 305, and an intermediate layer 303 that is therebetween and includes an emission layer. As shown in FIG. 6, the first pixel electrode 311 may be in contact with any one of the first source electrode 215a and the first drain electrode 215b through a contact hole formed in the planarization layer 140 or the like and may be electrically connected to the first subpixel circuit PC1. The first pixel electrode 311 may include a light-transmissive conductive layer and a reflective layer, wherein the light-transmissive conductive layer includes light-transmissive conductive oxide such as indium tin oxide (ITO), indium oxide (In₂O₃), or indium zinc oxide (IZO), and the reflective layer includes a metal such as Al or silver (Ag). For example, the first pixel electrode 311 may have a three-layer structure of ITO/Ag/ITO.

A light-emitting diode may also be located in the second subpixel PX2, the light-emitting diode including the second pixel electrode 312, the opposite electrode 305, and the intermediate layer 303 that is therebetween and includes an emission layer. In addition, a light-emitting diode may be located in the third subpixel PX3, the light-emitting diode including the third pixel electrode 313, the opposite electrode 305, and the intermediate layer 303 that is therebetween and includes an emission layer. The second pixel electrode 312 may be in contact with any one of the second source electrode 225a and the second drain electrode 225b through a contact hole formed in the planarization layer 140 or the like and may be electrically connected to the second subpixel circuit PC2. The third pixel electrode 313 may be in contact with any one of the third source electrode 235a and the third drain electrode 235b through a contact hole formed in the planarization layer 140 or the like and may be electrically connected to the third subpixel circuit PC3. The aforementioned description of the first pixel electrode 311 may apply to the second pixel electrode 312 and the third pixel electrode 313.

As described above, the intermediate layer 303 including the emission layer may be located not only on the first pixel electrode 311 of the first subpixel PX1 but also on the second pixel electrode 312 of the second subpixel PX2 and the third pixel electrode 313 of the third subpixel PX3. The intermediate layer 303 may have a shape integrally formed as a single body across the first pixel electrode 311, the second pixel electrode 312, and the third pixel electrode 313. The intermediate layer 303 may be patterned and located on the first pixel electrode 311, the second pixel electrode 312, and the third pixel electrode 313, as necessary. In addition to the emission layer, the intermediate layer 303 may include a hole injection layer, a hole transport layer, and/or an electron transport layer. Layers included in the intermediate layer 303 may also have a shape integrally formed as a single body across the first pixel electrode 311, the second pixel electrode 312, and the third pixel electrode 313. Some of the layers included in the intermediate layer 303 may also be patterned and located over the first pixel electrode 311, the second pixel electrode 312, and the third pixel electrode 313, as necessary. The emission layer included in the intermediate layer 303 may emit light having a wavelength in a first wavelength band. The first wavelength band may be, for example, about 450 nm to about 495 nm.

The intermediate layer 303 may not include one emission layer but may include a plurality of emission layers. For example, the intermediate layer 303 may also have a structure in which a first emission layer and a second emission layer are stacked, and a charge generation layer or the like is between the first emission layer and the second emission layer. In this case, a hole transport layer or an electron transport layer may also be between the first emission layer and the charge generation layer and between the second emission layer and the charge generation layer.

The opposite electrode 305 on the intermediate layer 303 may also have a shape integrally formed as a single body across the first pixel electrode 311 to the third pixel electrode 313. The opposite electrode 305 may include a light-transmissive conductive layer such as ITO, In₂O₃, or IZO and may also include a semi-transmissive layer including a metal such as Al, lithium (Li), magnesium (Mg), ytterbium (Yb), or Ag. For example, the opposite electrode 305 may include a semi-transmissive layer including MgAg, AgYb, Yb/MgAg, or Li/MgAg.

The pixel-defining layer 150 may be located on the planarization layer 140. The pixel-defining layer 150 has pixel openings corresponding to pixels. That is, the pixel-defining layer 150 may cover an edge of each of the first pixel electrode 311, the second pixel electrode 312, and the third pixel electrode 313 and may have a plurality of openings that expose central portions of the first pixel electrode 311, the second pixel electrode 312, and the third pixel electrode 313, respectively. As shown in FIG. 6, by increasing a distance between the opposite electrode 305 and the edge of each of the first pixel electrode 311, the second pixel electrode 312, and the third pixel electrode 313, the pixel-defining layer 150 may prevent an arc or the like from occurring on edges of the first pixel electrode 311, the second pixel electrode 312, and the third pixel electrode 313. The pixel-defining layer 150 may include, for example, an organic material such as polyimide or HMDSO.

The light-emitting diodes including the first pixel electrode 311, the second pixel electrode 312, and the third pixel electrode 313, the intermediate layer 303 including the emission layer, and the opposite electrode 305 may easily deteriorate due to moisture or oxygen. Accordingly, in order to protect the light-emitting diodes from external moisture or oxygen, the display apparatus may include the encapsulation layer 400 including the light-emitting diodes.

The encapsulation layer 400 may include at least one inorganic encapsulation layer and at least one organic encapsulation layer. For example, the encapsulation layer 400 may include a first inorganic encapsulation layer 410, a second inorganic encapsulation layer 430, and an organic encapsulation layer 420 therebetween.

Each of the first inorganic encapsulation layer 410 and the second inorganic encapsulation layer 430 may include at least one inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂), and may be formed using CVD or the like. The organic encapsulation layer 420 may include a polymer-based material. The polymer-based material may include silicone-based resin, acrylic resin (e.g., polymethyl methacrylate, polyacrylic acid, or the like), epoxy-based resin, polyimide, and polyethylene.

Because the first inorganic encapsulation layer 410 formed using CVD has a substantially uniform thickness, an upper surface of the first inorganic encapsulation layer 410 is not flat, as shown in FIG. 6. However, an upper surface of the organic encapsulation layer 420 has a substantially flat shape, and accordingly, the second inorganic encapsulation layer 430 on the organic encapsulation layer 420 may also have a substantially flat shape.

The second substrate 900 is located above the first substrate 100 such that the opposite electrode 305 is between the second substrate 900 and the first substrate 100. The second substrate 900 may include glass, metal, or polymer resin. The second substrate 900 may include polyethersulfone, polyacrylate, polyetherimide, polyethylene naphthalate, polyethylene terephthalate, polyphenylene sulfide, polyarylate, polyimide, polycarbonate, or cellulose acetate propionate. Various modifications may be made to the second substrate 900. For example, the second substrate 900 may have a multilayer structure including two layers and a barrier layer, wherein the two layers include the above polymer resin and the barrier layer includes an inorganic material (e.g., silicon oxide, silicon nitride, silicon oxynitride, or the like).

The bank layer 500 is located on a lower surface of the second substrate 900 in a direction (−Z direction) of the first substrate 100. The bank layer 500 has the first opening OP1 corresponding to the first subpixel PX1, the second opening OP2 corresponding to the second subpixel PX2, and the third opening OP3 corresponding to the third subpixel PX3. For example, the first opening OP1 of the bank layer 500 may overlap a first pixel opening that exposes the first pixel electrode 311 of the pixel-defining layer 150, the second opening OP2 of the bank layer 500 may overlap a second pixel opening that exposes the second pixel electrode 312 of the pixel-defining layer 150, and the third opening OP3 of the bank layer 500 may overlap a third pixel opening that exposes the third pixel electrode 313 of the pixel-defining layer 150. As described above, with respect to the first direction (e.g., the x-direction), in the openings of the bank layer 500, a width of each first portion may be greater than a width of each second portion, and thus, a width W11 of the first portion OP11 (see FIG. 5) of the first opening OP1 and a width W31 of the first portion OP31 (see FIG. 5) of the third opening OP3 may be greater than a width W22 of the second portion OP22 (see FIG. 5) of the second opening OP2.

The bank layer 500 may include various materials. For example, the bank layer 500 may include an organic material such as acryl, BCB, or HMDSO. The bank layer 500 may include a photoresist material, through which the bank layer 500 may be easily formed through processes such as exposure and development, as necessary. During a manufacturing process, the bank layer 500 is formed above the second substrate 900, and the light-transmissive layer 630, the first quantum dot layer 610, and the second quantum dot layer 620, which will be described below, are formed in the openings of the bank layer 500, and then, the first substrate 100 and the second substrate 900 are bonded using a bonding member or the like. Because the bank layer 500 is formed above the second substrate 900 through processes such as exposure and development, an area of a surface of the bank layer 500 in the direction (−Z direction) of the first substrate 100 is greater than an area of a surface of bank layer 500 in a direction (+Z direction) of the second substrate 900. Accordingly, in the cross-sectional view as shown in FIG. 6, the bank layer 500 may have an inversely tapered shape with respect to the second substrate 900.

In the third subpixel PX3, light having a wavelength in the first wavelength band generated in the intermediate layer 303 including the emission layer passes through the encapsulation layer 400 without converting the wavelength and is emitted to the outside. Accordingly, the light-transmissive layer 630 including light-transmissive resin may be located in the third opening OP3 of the bank layer 500 overlapping the third pixel electrode 313. In some cases, unlike shown in FIG. 6, the light-transmissive layer 630 may not be present in the third opening OP3 of the bank layer 500. The light-transmissive layer 630 may include light-transmissive resin and a scattering material.

The scattering material included in the light-transmissive layer 630 is not particularly limited as long as the scattering material may partially scatter transmitted light by forming an optical interface between the scattering material and the light-transmissive resin. For example, the scattering material may include metal oxide particles or organic particles. Metal oxide for scattering materials may include TiO₂, zirconium oxide (ZrO₂), Al₂O₃, In₂O₃, zinc oxide (ZnO), or tin oxide (SnO₂), and an organic material for scattering materials may include acrylic resin or urethane-based resin. The scattering material may scatter light in various directions regardless of an angle of incidence without substantially converting a wavelength of incident light. Accordingly, the scattering material may relatively improve the side visibility of the display apparatus.

The light-transmissive resin included in the light-transmissive layer 630 may be any material that has excellent dispersion characteristics for scattering materials and is light-transmissive. For example, polymer resin, such as acrylic resin, imide-based resin, epoxy-based resin, BCB, or HMDSO, may be used as the light-transmissive resin included in the light-transmissive layer 630. A material for forming the light-transmissive layer 630, which is a mixture of the light-transmissive resin and the scattering material, may be located in the third opening OP3 of the bank layer 500 overlapping the third pixel electrode 313 through an inkjet printing process.

The first quantum dot layer 610 may be located in the first opening OP1 of the bank layer 500. When seen in a direction (Z-axis direction) perpendicular to the first substrate 100, the first quantum dot layer 610 may overlap the first pixel electrode 311. Because the first quantum dot layer 610 includes quantum dots that may convert the wavelength of the incident light, light having a wavelength in the first wavelength band and passing through the first quantum dot layer 610 may be converted into light having a wavelength in a second wavelength band. The second wavelength band may be, for example, about 625 nm to about 780 nm. However, one or more embodiments are not limited thereto. A wavelength band to which a wavelength to be converted by the first quantum dot layer 610 belongs and a wavelength band to which the converted wavelength belongs may be differently modified.

The first quantum dot layer 610 may have a shape in which quantum dots are dispersed within resin. In the present disclosure, a quantum dot may refer to a crystal of a semiconductor compound and may include any material that may emit light having various emission wavelengths according to the size of the crystal. A diameter of the quantum dot may be, for example, about 1 nm to about 10 nm.

The quantum dots may be synthesized by a wet chemical process, an organometallic CVD process, a molecular beam epitaxy process, or similar processes. The wet chemical process refers to a method of growing quantum dot particle crystals after an organic solvent is mixed with a precursor material. In the wet chemical process, when crystals grow, the organic solvent naturally functions as a dispersant coordinated to the surface of quantum dot crystals and regulates the growth of the crystals, and thus, the wet chemical process is easier than vapor deposition methods such as metal organic CVD (MOCVD) or molecular beam epitaxy (MBE). In addition, the wet chemical process is a low-cost process and may control the growth of quantum dot particles.

The quantum dot may include a group II-VI semiconductor compound, a group III-V semiconductor compound, a group III-VI semiconductor compound, a group I-III-VI semiconductor compound, a group IV-VI semiconductor compound, a group IV element or compound, or any combinations thereof.

Examples of the group II-VI semiconductor compound may include a binary compound such as CdS, CdSe, CdTe, ZnS, ZnSe, ZnTe, ZnO, HgS, HgSe, HgTe, MgSe, or MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a quaternary compound such as CdZnSeS, CdZnSeTe, CdZnSTe, CdHgSeS, CdHgSeTe, CdHgSTe, HgZnSeS, HgZnSeTe, or HgZnST, or any combinations thereof.

Examples of the group III-V semiconductor compound may include a binary compound such as GaN, GaP, GaAs, GaSb, AlN, AlP, AlAs, AlSb, InN, InP, InAs, or InSb, a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, or GaAlNP, a quaternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, or any combinations thereof. Moreover, the group III-V semiconductor compound may further include a group II element. Examples of the group III-V semiconductor compound further including the group II element may include InZnP, InGaZnP, or InAlZnP.

Examples of the group III-VI semiconductor compound may include a binary compound such as GaS, GaSe, GazSes, GaTe, InS, In₂S₃, InSe, In₂Se₃, or InTe, a ternary compound such as AgInS, AgInS₂, CuInS, CuInS₂, InGaS₃, or InGaSe₃, or any combinations thereof.

Examples of the group I-III-VI semiconductor compound may include a ternary compound such as AgInS, AgInS₂, CuInS, CuInS₂, CuGaO₂, AgGaO₂, or AgAlO₂, or any combinations thereof.

Examples of the group IV-VI semiconductor compound may include a binary compound such as SnS, SnSe, SnTe, PbS, PbSe, or PbTe, a ternary compound such as SnSeS, SnSeTe, SnSTe, PbSeS, PbSeTe, PbSTe, SnPbS, SnPbSe, or SnPbTe, a quaternary compound such as SnPbSSe, SnPbSeTe, or SnPbSTe, or any combinations thereof.

The group IV element or compound may include a monoelement compound such as silicon (Si) or germanium (Ge), a binary compound such as SiC or SiGe, or any combinations thereof.

Each element included in a multi-element compound such as a binary compound, a ternary compound, and a quaternary compound may be present in particles at a uniform concentration or a non-uniform concentration.

In addition, the quantum dot may have a single structure or a core-shell dual structure in which the concentration of each element included in the quantum dot is uniform. For example, a material included in a core may be different from a material included in a shell. The shell of the quantum dot may function as a protective layer to maintain semiconductor characteristics by preventing chemical denaturation of the core and/or as a charging layer to impart electrophoretic characteristics to the quantum dot. The shell may include a single layer or a multilayer. An interface between the core and the shell may have a concentration gradient in which the concentration of an element present in the shell decreases toward the core.

Examples of the shell of the quantum dot may include metal or non-metal oxide, a semiconductor compound, or any combinations thereof. Examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, a ternary compound such as MgAl₂O₄, CoFe₂O₄, NiFe₂O₄, or CoMn₂O₄, or any combinations thereof. Examples of the semiconductor compound may include the group II-VI semiconductor compound, the group III-V semiconductor compound, the group III-VI semiconductor compound, the group I-III-VI semiconductor compound, the group IV-VI semiconductor compound, or any combinations thereof, as described above. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combinations thereof.

The quantum dot may have a full width of half maximum (FWHM) of an emission wavelength spectrum of about 45 nm or less, specifically, about 40 nm or less, and more specifically about 30 nm or less, and within this range, color purity and color reproducibility may be relatively improved. Also, because light emitted through the quantum dots is emitted in all directions, an optical field of view may be relatively improved.

Also, the shape of the quantum dot may be specifically spherical, pyramidal, multi-armed, or cubic, and may be in the form of nanoparticles, nanotubes, nanowires, nanofibers, or nanoplate-shaped particles.

Because an energy band gap may be adjusted by adjusting the size of the quantum dot, light in various wavelength bands may be obtained from a quantum dot emission layer. Accordingly, by using quantum dots of different sizes, a light-emitting element that emits light having various wavelengths may be implemented. For example, the size of the quantum dot may be selected such that red, green, and/or blue light is emitted. Also, the size of the quantum dot may be configured such that light of various colors are combined to emit white light.

The first quantum dot layer 610 may include a scattering material. As incident light is scattered by the scattering material included in the first quantum dot layer 610, the incident light may be efficiently converted by the quantum dots within the first quantum dot layer 610. The scattering material is not particularly limited as long as the scattering material may partially scatter transmitted light by forming an optical interface between the scattering material and the light-transmissive resin. The foregoing description regarding the material for scattering materials included in the light-transmissive layer 630 may apply to the material for scattering materials included in the first quantum dot layer 610. The scattering material may scatter light in various directions regardless of an angle of incidence without substantially converting a wavelength of incident light. Accordingly, the scattering material may relatively improve the side visibility of the display apparatus. Also, the scattering material included in the first quantum dot layer 610 may increase light conversion efficiency by increasing the probability that incident light incident on the first quantum dot layer 610 encounters quantum dots.

The resin included in the first quantum dot layer 610 may be any material that has excellent dispersion characteristics for scattering materials and is light-transmissive. For example, polymer resin, such as acrylic resin, imide-based resin, epoxy-based resin, BCB, or HMDSO, may be used as a material for forming the first quantum dot layer 610. The material for forming the first quantum dot layer 610 may be located in the first opening OP1 of the bank layer 500 overlapping the first pixel electrode 311 through an inkjet printing process, the first quantum dot layer 610 including the resin and the scattering material.

The second quantum dot layer 620 may be located in the second opening OP2 of the bank layer 500. When seen in the direction (Z-axis direction) perpendicular to the first substrate 100, the second quantum dot layer 620 may overlap the second pixel electrode 312.

Because the second quantum dot layer 620 includes quantum dots that may convert the wavelength of the incident light, light having a wavelength in the first wavelength band and passing through the second quantum dot layer 620 may be converted into light having a wavelength in a third wavelength band. The third wavelength band may be, for example, 495 nm to about 570 nm. However, one or more embodiments are not limited thereto. A wavelength band to which a wavelength to be converted by the second quantum dot layer 620 belongs and a wavelength band to which the converted wavelength belongs may be differently modified.

The second quantum dot layer 620 may have a shape in which quantum dots are dispersed within resin. In the present disclosure, a quantum dot may refer to a crystal of a semiconductor compound and may include any material that may emit light having various emission wavelengths according to the size of the crystal. The diameter of the quantum dot may be, for example, about 1 nm to about 10 nm. Because the above description of quantum dots included in the first quantum dot layer 610 may apply to quantum dots included in the second quantum dot layer 620, the description of the quantum dots included in the second quantum dot layer 620 is not provided.

The second quantum dot layer 620 may include a scattering material. As incident light is scattered by the scattering material included in the second quantum dot layer 620, the incident light may be efficiently converted by the quantum dots within the second quantum dot layer 620. The scattering material is not particularly limited as long as the scattering material may partially scatter transmitted light by forming an optical interface between the scattering material and the light-transmissive resin. For example, the scattering material may include metal oxide particles or organic particles. The same foregoing description applies to metal oxide for scattering materials or organic materials for scattering materials. The scattering material may scatter light in various directions regardless of an angle of incidence without substantially converting a wavelength of incident light. Accordingly, the scattering material may relatively improve the side visibility of the display apparatus. Also, the scattering material included in the second quantum dot layer 620 may increase light conversion efficiency by increasing the probability that incident light incident on the second quantum dot layer 620 encounters quantum dots.

The resin included in the second quantum dot layer 620 may be any material that has excellent dispersion characteristics for scattering materials and is light-transmissive. For example, polymer resin, such as acrylic resin, imide-based resin, epoxy-based resin, BCB, or HMDSO, may be used as a material for forming the second quantum dot layer 620. The material for forming the second quantum dot layer 620 may be located in the second opening OP2 of the bank layer 500 overlapping the second pixel electrode 312 through an inkjet printing process, the second quantum dot layer 620 including the resin and the scattering material.

A surface of the bank layer 500 in the direction (−Z direction) of the first substrate 100, a surface of the light-transmissive layer 630 in the direction (−Z direction) of the first substrate 100, a surface of the first quantum dot layer 610 in the direction (−Z direction) of the first substrate 100, and a surface of the second quantum dot layer 620 in the direction (−Z direction) of the first substrate 100 may be covered by a protective layer 510. The protective layer 510 may protect the light-transmissive layer 630, the first quantum dot layer 610, and the second quantum dot layer 620. The protective layer may include an inorganic material such as silicon nitride, silicon oxide, or silicon oxynitride.

A color filter layer may be between the light-transmissive layer 630 and the first quantum dot layer 610 and between the second quantum dot layer 620 and the second substrate 900. The first color filter 810 may be located above the first quantum dot layer 610, the second color filter 820 may be located above the second quantum dot layer 620, and the third color filter 830 may be located above the light-transmissive layer 630. The first color filter 810 may be a layer that only passes light having a wavelength ranging from about 625 nm to about 780 nm. The second color filter 820 may be a layer that only passes light having a wavelength ranging from about 495 nm to about 570 nm. The third color filter 830 may be a layer that only passes light having a wavelength ranging from about 450 nm to about 495 nm.

The first to third color filters 810 to 830 may relatively improve the quality of displayed images by increasing the color purity of light emitted to the outside. Also, the first to third color filters 810 to 830 lower a rate at which external light incident on the display apparatus from the outside is reflected by the first to third pixel electrodes 311 to 313 and then emitted again to the outside, and may thus reduce external light reflection. A black matrix may be between the first to third color filters 810 to 830, as necessary.

Moreover, an area where two or more color filters overlap may function as a black matrix. For example, this is because, in theory, when the first color filter 810 passes only light having a wavelength ranging from about 625 nm to about 780 nm, the second color filter 820 passes only light having a wavelength ranging from about 495 nm to about 570 nm, and the third color filter 830 passes only light having a wavelength ranging from about 450 nm to about 495 nm, there is no light that may pass all of the first, second, and third color filters 810, 820, and 830 in an area where the first, second, and third color filters 810, 820, and 830 overlap. Accordingly, as the area where all of the first, second, and third color filters 810, 820, and 830 overlap is present between the first, second, and third subpixels PX1, PX2, and PX3, color filters may reliably function as black matrices between the first, second, and third subpixels PX1, PX2, and PX3.

A low refractive index layer 700 may be between the first, second, and third color filters 810, 820, and 830, the bank layer 500, the light-transmissive layer 630, the first quantum dot layer 610, and the second quantum dot layer 620. During the manufacturing process, the low refractive index layer 700 may cover the first, second, and third color filters 810, 820, and 830, and the bank layer 500 may be formed on an upper surface of the low refractive index layer 700. The low refractive index layer 700 may include, for example, an inorganic material such as silicon oxide, silicon nitride, or silicon oxynitride, and may be formed using a CVD method.

The first substrate 100 and the second substrate 900 may be bonded outside the display area by using a bonding member such as a sealant. In this, a filler 520 may be filled between a laminate on the first substrate 100 and a laminate on the second substrate 900, as necessary. For example, the filler 520 may be filled between the encapsulation layer 400 and the protective layer 510. Such a filler may include acrylic resin or epoxy resin.

FIG. 7 is a schematic plan view of the display apparatus according to some embodiments. Referring to FIG. 7, except for the features of the first to sixth openings OP1, OP2, OP3, OP4, OP5, and OP6, other features are the same as those described in FIGS. 5 and 6. Among the components in FIG. 7, the same reference numerals replace those previously described with reference to FIGS. 5 and 6, and differences will be mainly described below.

Referring to FIG. 7, the bank layer 500 may include the first opening OP1 corresponding to the first subpixel PX1, the second opening OP2 corresponding to the second subpixel PX2, the third opening OP3 corresponding to the third subpixel PX3, the fourth opening OP4 corresponding to the fourth subpixel PX4, the fifth opening OP5 corresponding to the fifth subpixel PX5, and the sixth opening OP6 corresponding to the sixth subpixel PX6. Also, each of the plurality of openings of the bank layer 500 may include a first portion including the inkjet area IA, and a second portion extending in the second direction (e.g., the y-direction) from one side of the first portion.

For example, the first opening OP1 may include the first portion OP11 and the second opening OP12, the second opening OP2 may include the first portion OP21 and the second portion OP22, and the third opening OP3 may include the first portion OP31 and the second portion OP32. Similarly, the fourth opening OP4 may include the first portion OP41 and the second portion OP42, the fifth opening OP5 may include the first portion OP51 and the second portion OP52, and the sixth opening OP6 may include the first portion OP61 and the second portion OP62.

As described above, each of the first portions OP11, OP21, OP31, OP41, OP51, and OP61 is an area where ink may be dropped, and the inkjet area IA described above may be arranged in each of the first portions OP11, OP21, OP31, OP41, OP51, and OP61. Accordingly, an area of each of the first portions OP11, OP21, OP31, OP41, OP51, and OP61 may be greater than an area of the inkjet area IA (see FIG. 5). The inkjet area IA (see FIG. 5) may require at least one of the horizontal width IW (see FIG. 5) or the vertical width IH (see FIG. 5) to be 35 μm or more, the inkjet area IA (see FIG. 5) may have a regular octagonal shape with the horizontal width IW (see FIG. 5) and the vertical width IH (see FIG. 5) of 35 μm.

According to some embodiments, each of the first portions OP11, OP21, OP31, OP41, OP51, and OP61 may have a regular octagonal shape, with a portion thereof being greater than or equal to the inkjet area IA. When each of the first to sixth openings OP1, OP2, OP3, OP4, OP5, and OP6 has an L-shape, the first portions OP11, OP21, OP31, OP41, OP51, and OP61 may not have a complete regular octagonal shape, but only sides of the first portions OP11, OP21, OP31, OP41, OP51, and OP61, which are not connected to the second portions OP12, OP22, OP32, OP42, OP52, and OP62, may have a regular octagonal shape. In this case, the first portions OP11, OP21, OP31, OP41, OP51, and OP61 may have a heptagonal shape, as shown in FIG. 7. According to some embodiments, when each of the first to sixth openings OP1, OP2, OP3, OP4, OP5, and OP6 has a T-shape, the first portions OP11, OP21, OP31, OP41, OP51, and OP61 may have a regular octagonal shape. However, one or more embodiments are not limited. The first portions OP11, OP21, OP31, OP41, OP51, and OP61 may have a circular, quadrangular, or polygonal planar shape. As the first portions OP11, OP21, OP31, OP41, OP51, and OP61 may have various planar shapes as described above, in the display apparatus according to some embodiments, the first to sixth subpixels PX1, PX2, PX3, PX4, PX5, and PX6 may be efficiently arranged in a limited space, and high-resolution images with excellent quality may be implemented.

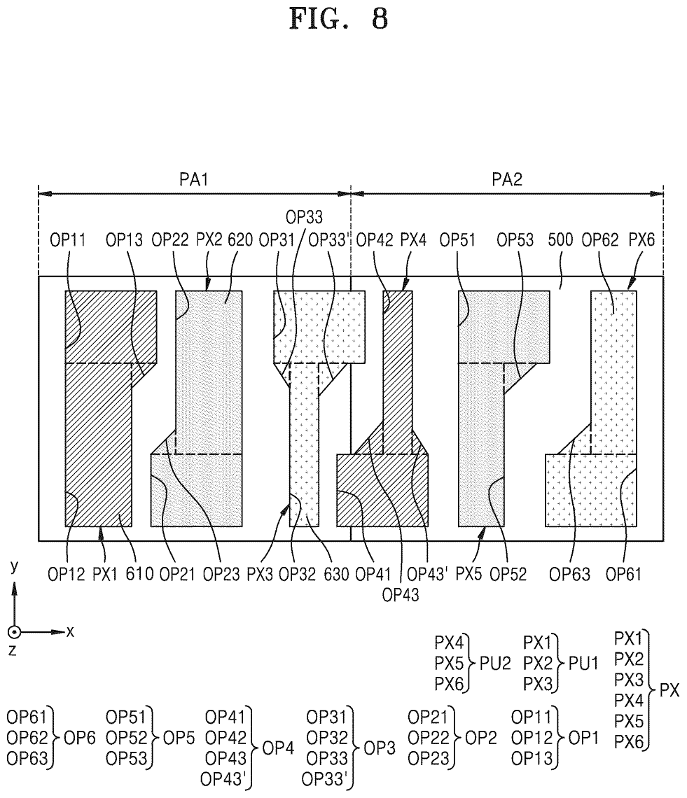

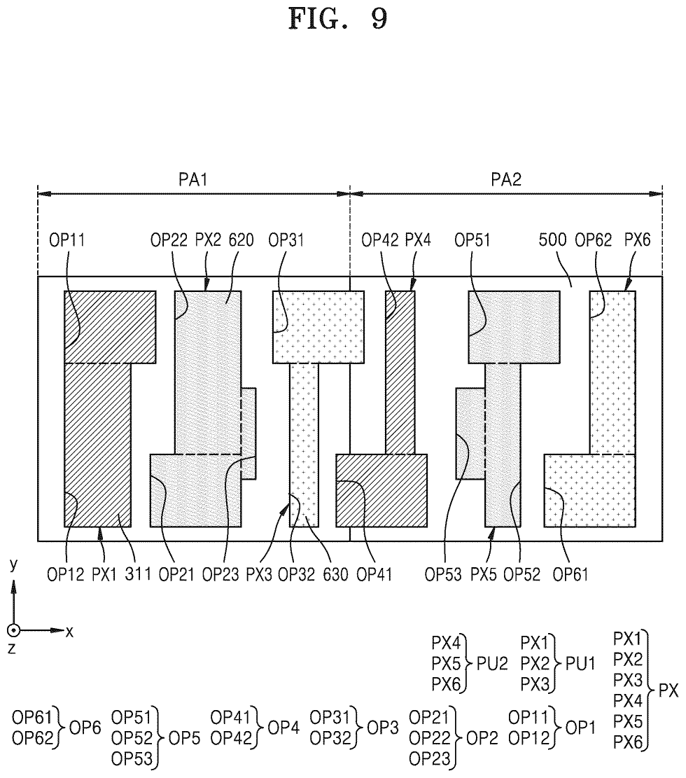

FIG. 8 is a schematic plan view of the display apparatus according to some embodiments, and FIG. 9 is a schematic plan view of the display apparatus according to some embodiments. Referring to FIGS. 8 and 9, except for the features of the first to sixth openings OP1, OP2, OP3, OP4, OP5, and OP6, other features are the same as those described in FIGS. 5 and 6. Among the components in FIGS. 8 and 9, the same reference numerals replace those previously described with reference to FIGS. 5 and 6, and differences will be mainly described below.

Referring to FIGS. 8 and 9, the bank layer 500 may include the first opening OP1 corresponding to the first subpixel PX1, the second opening OP2 corresponding to the second subpixel PX2, the third opening OP3 corresponding to the third subpixel PX3, the fourth opening OP4 corresponding to the fourth subpixel PX4, the fifth opening OP5 corresponding to the fifth subpixel PX5, and the sixth opening OP6 corresponding to the sixth subpixel PX6.

Each of the plurality of openings of the bank layer 500 may include a first portion including the inkjet area IA, and a second portion extending in the second direction (e.g., the y-direction) from one side of the first portion. Each of the first portions OP11, OP21, OP31, OP41, OP51, and OP61 has a quadrangular shape greater than the inkjet area IA, and widths of the second portions in the first direction (e.g., the x-direction) may be less than widths of the first portions in the first direction (e.g., the x-direction).

Due to the above structure, at least one of the first to sixth openings OP1, OP2, OP3, OP4, OP5, or OP6 may have an L-shape. Also, according to some embodiments, at least one of the first to sixth openings OP1, OP2, OP3, OP4, OP5, or OP6 may have an L-shape. Referring to FIG. 9, as the second portion OP32 of the third opening OP3 is arranged at the center of the first portion OP31 of the third opening OP3 or one side of the first portion OP31 of the third opening OP3, the third opening OP3 may have a T-shape. For example, a left end of the first portion OP31 of the third opening OP3 may be arranged to protrude further than a left end of the second portion OP32 of the third opening OP3, and a right end of the first portion OP31 of the third opening OP3 may be arranged to protrude further than a right end of the second portion OP32 of the third opening OP3.

In addition, according to some embodiments, each of the plurality of openings of the bank layer 500 may further include a third portion. In this case, the third portion may be a portion extending from at least one of the first portion or the second portion.

First, referring to FIG. 8, the first opening OP1 may further include a third portion OP13, the second opening OP2 may further include a third portion OP23, and the third opening OP3 may further include third portions OP33 and OP33′. The fourth opening OP4 may further include third portions OP43 and OP43′, the fifth opening OP5 may further include a third portion OP53, and the sixth opening OP6 may further include a third portion OP63.

According to some embodiments, each of the third portions OP13, OP23, OP33, OP43, OP53, and OP63 may have a triangular shape, as shown in FIG. 8. As shown in FIG. 8, when the plurality of openings have an L-shape or T-shape, a width of the second portion is less than a width of the first portion, and thus, a surplus area without subpixels PX may be generated. In this case, the third portions OP13, OP23, OP33, OP43, OP53, and OP63 each having a triangular shape may be arranged at corners where ends of the first portions and ends of the second portions meet, respectively. As the third portions OP13, OP23, OP33, OP43, OP53, and OP63 are additionally arranged, greater areas may be secured for the first to sixth openings OP1, OP2, OP3, OP4, OP5, and OP6, allowing for more freedom in design.

Next, referring to FIG. 9, the second opening OP2 may further include the third portion OP23, and the fifth opening OP5 may further include the third portion OP53. According to some embodiments, each of the third portions OP23 and OP53 may have a quadrangular shape.

As shown in FIG. 9, when the third opening OP3 and the fourth opening OP4 have a T-shape, a distance between the second opening OP2 and the third opening OP3 or a distance between the fourth opening OP4 and the fifth opening OP5 increases such that a surplus area may be generated. In this case, the third portion OP23 of the second opening OP2 may be arranged on a side facing the third opening OP3 among sides of the second opening OP2, securing a greater area for the second opening OP2. Similarly, the third portion OP53 of the fifth opening OP5 may be arranged on a side facing the third opening OP3 among sides of the fifth opening OP5, securing a greater area for the fifth opening OP5.

In other words, as shown in FIGS. 8 and 9, when the openings of the bank layer 500 further includes the third portions OP13, OP23, OP33, OP43, OP53, and OP63, greater areas may be secured for the first to sixth subpixels PX1, PX2, PX3, PX4, PX5, and PX6 such that the plurality of subpixels PX may be designed more freely within the first pixel area PA1 and the second pixel area PA2. That is, in the display apparatus according to some embodiments, the first to sixth subpixels PX1, PX2, PX3, PX4, PX5, and PX6 may be efficiently arranged by using the third portions, and accordingly, high-resolution images with more excellent quality may be implemented.

As described above, the one or more embodiments have been described with reference to the accompanying drawings, but the embodiments should be considered in a descriptive sense only. Those of ordinary skill in the art will understand that various modifications and changes to the embodiments may be made therefrom. Therefore, the true technical scope of protection of the disclosure should be defined by the technical spirit of the appended claims.

As described above, the display apparatus according to the one or more embodiments may have relatively improved resolution and implement images with relatively excellent quality. However, the aforementioned effects are examples, and do not limit the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate including a first pixel area and a second pixel area adjacent to the first pixel area, wherein a first subpixel, a second subpixel, and a third subpixel are arranged in the first pixel area and are configured to emit light of different colors;
a plurality of light-emitting elements on the substrate to respectively correspond to the first subpixel, the second subpixel, and the third subpixel; and
a bank layer on the plurality of light-emitting elements and including a first opening, a second opening, and a third opening, the first opening corresponding to the first subpixel, the second opening corresponding to the second subpixel, and the third opening corresponding to the third subpixel,
wherein the first opening, the second opening, and the third opening are arranged in a first direction, and
a first portion of the third opening extends in the first direction and overlaps the second pixel area.

2. The display apparatus of claim 1, wherein a fourth subpixel, a fifth subpixel, and a sixth subpixel are arranged in the second pixel area, the fourth subpixel, the fifth subpixel, and the sixth subpixel configured to emit light of different colors,
the bank layer further includes a fourth opening corresponding to the fourth subpixel, a fifth opening corresponding to the fifth subpixel, and a sixth opening corresponding to the sixth subpixel,
the fourth opening, the fifth opening, and the sixth opening are arranged in the first direction, and
a first portion of the fourth opening extends in an opposite direction to the first direction and overlaps the first pixel area.

3. The display apparatus of claim 2, wherein the first pixel area and the second pixel area are repeatedly arranged.

4. The display apparatus of claim 2, wherein the first subpixel and the fourth subpixel are configured to emit light of a same color,
the second subpixel and the fifth subpixel are configured to emit light of a same color, and
the third subpixel and the sixth subpixel are configured to emit light of a same color.

5. The display apparatus of claim 4, wherein the first opening and the fourth opening have a same area but different shapes, and
the third opening and the sixth opening have a same area but different shapes.

6. The display apparatus of claim 2, wherein each of the first to the sixth openings includes a first portion and a second portion that extends from one side of the first portion in a second direction crossing the first direction, and
a width of the first portion in the first direction is greater than a width of the second portion in the first direction.

7. The display apparatus of claim 6, wherein an area of the first portion of the third opening is greater than an area of the first portion of the sixth opening, and
an area of the second portion of the third opening is less than an area of the second portion of the sixth opening.

8. The display apparatus of claim 7, wherein an area of the first portion of the fourth opening is greater than an area of the first portion of the first opening, and
an area of the second portion of the fourth opening is less than an area of the second portion of the first opening.

9. The display apparatus of claim 6, wherein, with respect to the second direction, each of the first opening, the third opening, and the fifth opening has the first portion in an upper portion thereof and the second portion in a lower portion thereof, and each of the second opening, the fourth opening, and the sixth opening has the second portion in an upper portion thereof and the first portion in a lower portion thereof.

10. The display apparatus of claim 6, wherein, with respect to the second direction, the first portion of the third opening faces the first portion of the fourth opening.

11. The display apparatus of claim 6, wherein at least a portion of the first portion has a circular, quadrangular, or polygonal planar shape.

12. The display apparatus of claim 6, wherein at least one of the first to the sixth openings further includes a third portion, and
the third portion is a portion that extends from at least one of the first portion or the second portion.

13. The display apparatus of claim 1, wherein at least one of the first to third openings has an L-shape or a T-shape.

14. The display apparatus of claim 1, further comprising a quantum dot layer or a light-transmissive layer located in the first to third openings.

15. A display apparatus comprising a first pixel unit and a second pixel unit, the first pixel unit including a first subpixel, a second subpixel, and a third subpixel that are configured to emit light of different colors, and the second pixel unit including a fourth subpixel, a fifth subpixel, and a sixth subpixel that are configured to emit light of different colors, the display apparatus comprising:
a plurality of light-emitting elements arranged to respectively correspond to the first to sixth subpixels; and
a bank layer on the plurality of light-emitting elements and including a first opening, a second opening, a third opening, a fourth opening, a fifth opening, and a sixth opening, the first opening corresponding to the first subpixel, the second opening corresponding to the second subpixel, the third opening corresponding to the third subpixel, the fourth opening corresponding to the fourth subpixel, the fifth opening corresponding to the fifth subpixel, and the sixth opening corresponding to the sixth subpixel,
wherein the first to the sixth openings are arranged in a first direction,
a first portion of the third opening extends in the first direction,
a first portion of the fourth opening extends in an opposite direction to the first direction, and
with respect to a second direction crossing the first direction, the first portion of the third opening faces the first portion of the fourth opening.

16. The display apparatus of claim 15, wherein the first pixel unit and the second pixel unit are repeatedly arranged.

17. The display apparatus of claim 15, wherein the first subpixel and the fourth subpixel are configured to emit light of a same color,
the second subpixel and the fifth subpixel are configured to emit light of a same color, and
the third subpixel and the sixth subpixel are configured to emit light of a same color.

18. The display apparatus of claim 17, wherein the first opening and the fourth opening have a same area but different shapes, and
the third opening and the sixth opening have a same area but different shapes.

19. The display apparatus of claim 15, wherein at least one of the first to the sixth openings has an L-shape or a T-shape.

20. The display apparatus of claim 19, wherein the first opening and the second opening alternate with each other,
the third opening and the fourth opening alternate with each other, and
the fifth opening and the sixth opening alternate with each other.

21. The display apparatus of claim 15, wherein each of the first to the sixth openings includes a first portion and a second portion that extends from one side of the first portion in the second direction, and
a width of the first portion in the first direction is greater than a width of the second portion in the first direction.

22. The display apparatus of claim 21, wherein an area of the first portion of the third opening is greater than an area of the first portion of the sixth opening, and
an area of the first portion of the fourth opening is greater than an area of the first portion of the first opening.
